(19) United States
(12) Patent Application Publication
(10) Pub. No.: US 2026/0177903 A1
(43) Pub. Date: Jun. 25, 2026

(54) VIEWER WITH AUTOMATIC OPACITY ADJUSTMENT OF IMAGE MASK

(71) Applicant: Leica Biosystems Imaging, Inc., Vista, CA (US)

(72) Inventors: Lopa CHOKSI, San Diego, CA (US); Jason SLOCOMB, Poway, CA (US); Andrea BATY, Candler, NC (US); Will CLARDY, Louisville, KY (US)

(21) Appl. No.: 19/535,115

(22) Filed: Feb. 10, 2026

Related U.S. Application Data
(63) Continuation of application No. PCT/US2024/042201, filed on Aug. 14, 2024.
(60) Provisional application No. 63/579,074, filed on Aug. 28, 2023.

(51) Int. Cl. G03F 1/36; G06F 3/0482; G06F 3/04847; G06T 15/50; H04N 23/69

(52) U.S. Cl. CPC G03F 1/36; G06F 3/0482; G06F 3/04847; G06T 15/503; H04N 23/69

(57) ABSTRACT

An apparatus for interacting with one or more digital whole slide images (WSIs) acquired by an imaging device includes a display, a memory, and one or more hardware processors. The memory is configured to store computer-executable instructions. The one or more hardware processors are in communication with the display and the memory. The one or more hardware processors are configured to drive the display using the computer-executable instructions of the memory such that the one or more hardware processors are configured to generate a user interface. The user interface includes an image layer and one or more mask layers overlaying the image layer. The one or more mask layers have a predetermined opacity level. The one or more hardware processors are further configured to automatically adjust the predetermined opacity level as a function of a magnification level of the image layer.

### PRIORITY

This application claims priority to U.S. Provisional Application Ser. No. 63/579,074, entitled “Viewer with Automatic Opacity Adjustment of Image Mask,” filed on Aug. 28, 2023, the disclosure of which is incorporated by reference herein.

### BACKGROUND

Tissue samples may be analyzed microscopically for various diagnostic purposes, including detecting the presence of cancer by identifying structural abnormalities in the tissue samples. During such analysis, a tissue sample may be embedded and then sectioned into multiple separate sections. Each section may then be placed onto an individual slide. The tissue section on each slide may be stained to improve contrast and/or highlight regions of interest. Each slide may then be imaged to form a digital whole slide image (WSI). Individual digital WSI's may be analyzed to identify structural features in the tissue sample. Analysis of such WSI's may be referred to as digital pathology in some circumstances.

Merely exemplary devices and systems for use in digital pathology are disclosed in U.S. Pat. No. 10,732,394, entitled “Managing Plural Scanning Devices in a High-Throughput Laboratory Environment,” issued on Aug. 4, 2020; U.S. Pat. No. 7,738,688, entitled “System and Method for Viewing Virtual Slides,” issued on Jun. 15, 2010; and U.S. Pub. No. 2022/0309670, entitled “Method and System for Visualizing Information on Gigapixels Whole Slide Image,” published on Sep. 29, 2022, the disclosures of which are hereby incorporated by reference herein.

In some circumstances, it may be beneficial to use one or more image masks in connection with analysis of images. For instance, various forms of artificial intelligence and/or machine learning may be used to generate images masks based on characteristics within one or more images. In one example, such image masks may be used in combination with one or more digital WSI's within a digital pathology environment. In such circumstances, a machine learning diagnostics system can be used to diagnose diseases or other conditions based on a histopathology image. Typically, such systems employ artificial intelligence to identify patterns in this histopathology image which can be used to generate a diagnosis, which may be graphically illustrated in the form of one or more image masks. Such systems may be implemented in combination with conventional human-based analysis. In other words, such systems may be used as a supplement to human-based analysis of digital WSI's. It may be therefore desirable to provide certain user interface features within a digital pathology environment to implement combined digital WSI analysis modalities.

While several systems and methods have been made and used for analyzing images, it is believed that no one prior to the inventor has made or used the invention described in the appended claims.

### BRIEF DESCRIPTION OF THE DRAWINGS

While the specification concludes with claims which particularly point out and distinctly claim this technology, it is believed this technology will be better understood from the following description of certain examples taken in conjunction with the accompanying drawings, in which like reference numerals identify the same elements and in which:

FIG. 1 depicts an exemplary environment of an imaging system;

FIG. 2 depicts an exemplary computing system that may implement any one or more of the imaging devices, image analysis system, user computing device(s), interface server, machine learning server, and other components described herein;

FIG. 3 depicts an exemplary user interface for use with the imaging system of FIG. 1 and the computing system of FIG. 2;

FIG. 4 depicts the user interface of FIG. 3, with an image layer adjusted to a 10× magnification level;

FIG. 5 depicts the user interface of FIG. 3, with the image layer adjusted to a 20× magnification level;

FIG. 6 depicts the user interface of FIG. 3, with the image layer adjusted to a 40× magnification level; and

FIG. 7 depicts a detailed view of the user interface of FIG. 3, with the image layer at a 1× magnification level and details of one or more mask boundaries visible; and

FIG. 8 depicts anther detailed view of the user interface of FIG. 3, with the image layer at a 40× magnification level and the details of one or more mask boundaries visible.

The drawings are not intended to be limiting in any way, and it is contemplated that various embodiments of the technology may be carried out in a variety of other ways, including those not necessarily depicted in the drawings. The accompanying drawings incorporated in and forming a part of the specification illustrate several aspects of the present technology, and together with the description serve to explain the principles of the technology; it being understood, however, that this technology is not limited to the precise arrangements shown.

### DETAILED DESCRIPTION

The following description of certain examples of the technology should not be used to limit its scope. Other examples, features, aspects, embodiments, and advantages of the technology will become apparent to those skilled in the art from the following description, which is by way of illustration, one of the best modes contemplated for carrying out the technology. As will be realized, the technology described herein is capable of other different and obvious aspects, all without departing from the technology. Accordingly, the drawings and descriptions should be regarded as illustrative in nature and not restrictive.

### I. OVERVIEW OF EXEMPLARY IMAGING SYSTEM

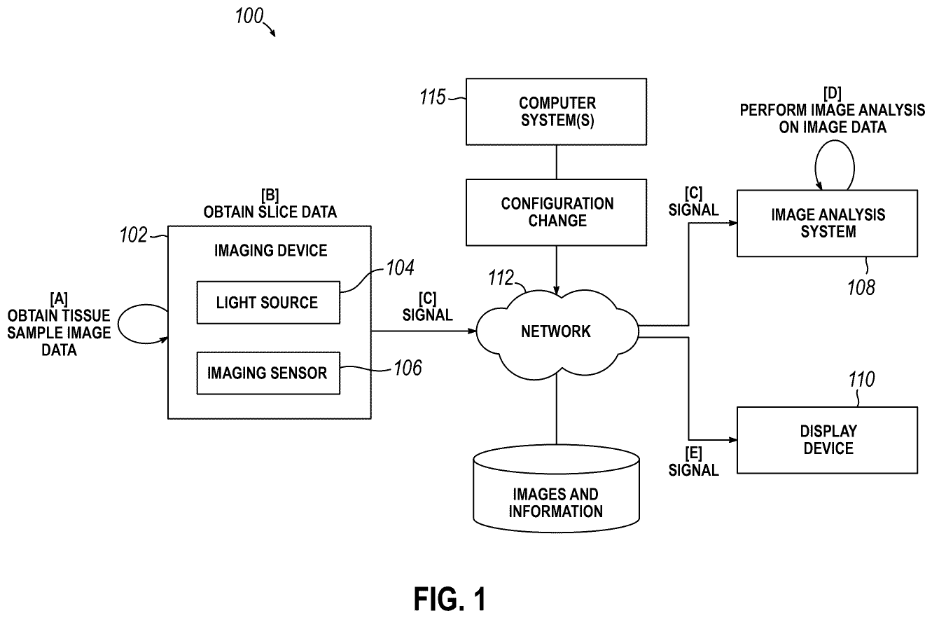

FIG. 1 shows an exemplary environment (100) (e.g., an imaging system) in which an operator and/or the imaging system may analyze a sample. Environment (100) includes an automated slide stainer that is controlled to produce consistently stained slides based on one or more protocols. Environment (100) may also include an imaging device (102) that generates a digital representation (e.g., an image) of a stained slide. The digital representation may be communicated as signal [C] to a network (112) and then to an image analysis system (108) for processing (e.g., feature detection, feature measurements, etc.). Image analysis system (108) may perform image analysis on received image data. Image analysis system (108) may normalize the image data obtained for input to a machine learning algorithm and/or model, which may determine characteristics of the image. Results from image analysis system (108) may be communicated as a signal [E] to one or more display devices (110) (which also may be referred to herein as a “display device” or a “client device”).

In some examples, the imaging device (102) includes a light source (104) configured to emit light onto the tissue sample(s) and the imaging sensor 106 configured to detect light emitted from the tissue sample. In some examples, light source (104) and imaging sensor (106) may be configured for use with multispectral imaging. In such examples, the multispectral imaging using the light source 104 may involve providing light to the tissue sample carried by a carrier within a range of frequencies. Thus, light source (104) may be configured to generate light across a spectrum of frequencies to provide multispectral imaging.

In some examples, the tissue sample may reflect light received from light source (104), which may then be detected at imaging sensor (106). In such examples, light source (104) and imaging sensor (106) may be located on substantially the same side of the tissue sample. In other examples, light source (104) and imaging sensor (106) may be located on opposing sides of the tissue sample.

Imaging device (102) is configured to capture and/or generate image data for analysis. To facilitate such functionality, imaging device (102) may include one or more of a lens, an image sensor, a processor, or memory. Imaging device (102) may further be configured to receive an operator interaction. The operator interaction may be a request to capture image data. Based on the operator interaction, imaging device (102) may capture image data. Imaging device (102) may further be configured to store the image data and other information in the images and other information within an information database (113). Imaging device (102) may further be configured to receive image data from additional imaging devices. For instance, imaging device (102) may be a node that routes image data from other imaging devices to image analysis system (108). In some examples, imaging device (102) may be located within image analysis system (108) as a component thereof. In other examples, imaging device (102) and image analysis system (108) may be in communication with each other (e.g., wirelessly or wired connection). For instance, imaging device (102) and image analysis system (108) may communicate over network (112). In some examples, image analysis system (108) may be connected to (via a wired or a wireless connection) a plurality of imaging devices.

In some examples, image analysis system (108) is in communication with one or more display devices (110). Such communication may be desirable to facilitate operator input or to provide a recommendation for a set of image data. For instance, image analysis system (108) may be configured to transmit the recommendation to display device (110) via network (112). In some examples, image analysis system (108) is configured to operate cooperatively with a computing system (200) described in greater detail below. As will be described in greater detail below, computing system (200) may be configured to engage and disengage with image analysis system (108) in order to receive the recommendation. For instance, display device (110) may engage with image analysis system (108) upon determining that image analysis system (108) has generated a recommendation for display device (110). Further, the display devices (110) may connect to image analysis system (108) based on image analysis system (108) performing image analysis on image data that corresponds to a particular computing system (200). For instance, a user may be associated with a plurality of histological samples. Upon determining, that a particular histological sample is associated with a particular user and a corresponding display device (110), image analysis system (108) may transmit a recommendation for the histological sample to the particular display device (110). In some embodiments, display device (110) may dock with image analysis system (108) in order to receive the recommendation.

Imaging device (102), image analysis system (108), and/or the display device (110) are in communication with each other via network (112). Network (112) can include a variety of communication modalities, such as wired and/or wireless modalities and/or technologies. Network (112) can include combination of Personal Area Networks (“PANs”), Local Area Networks (“LANs”), Campus Area Networks (“CANs”), Metropolitan Area Networks (“MANs”), extranets, intranets, the Internet, short-range wireless communication networks (e.g., ZigBee, Bluetooth, etc.), Wide Area Networks (“WANs”)—both centralized and/or distributed—and/or any combination, permutation, and/or aggregation thereof. Network (112) may include, and/or may or may not have access to and/or from, the internet.

Imaging device (102) and image analysis system (108) are configured to communicate image data. For instance, imaging device (102) is configured to communicate image data associated with a histological sample to image analysis system (108) via network (112) for analysis. Image analysis system (108) and display device (110) are configured to communicate a recommendation corresponding to the image data. For instance, image analysis system (108) can communicate a diagnosis regarding whether the image data is indicative of a disease present in the tissue sample. In some examples, imaging device (102) and image analysis system (108) are configured to communicate via a first network and image analysis system (108) and display device (110) are configured to communicate via a second network. In other examples, imaging device (102), image analysis system (108), and display device (110) may communicate over the same network (112).

Environment (100) further includes one or more computer systems (115) (“computer system 115”) configured to communicate with imaging device (102), image analysis system (108), and/or display device (110). In some examples, computer system (115) is configured to communicate directly with imaging device (102), image analysis system (108), and/or display device (110) directly or via network (112).

In some examples, computer system (115) is configured to provide information to change functionality or operation of imaging device 102, image analysis system (108), display device (110), and/or network (112). For instance, the information may be new software, a software update, new or revised lookup tables, or data or any other type of information that is used in any way to generate, manipulate, transfer or render an image (all being referred to herein as an “update” for ease of reference). The update may be related to, for example, image compression, image transfer, image storage, image display, image rendering, etc. In some examples, computer system (115) is configured to provide a message to the device or system to be updated, or is configured to provide a message to a user who interacts with the system control updating the system. In some examples, the update is provided automatically, e.g., periodically or as needed/available. In other examples, the update is provided in response to receiving an indication from an operator to provide the update (e.g., affirmation for the update or a request for the update).

In the example shown in FIG. 1, at [A], imaging device (102) may obtain block data. In order to obtain the block data, imaging device (102) may image (e.g., scan, capture, record, etc.) a tissue block. The tissue block may be a histological sample. For instance, the tissue block may be a block of biological tissue that has been removed and prepared for analysis. As will be described in greater detail below, in order to prepare the tissue block for analysis, various histological techniques may be performed on the tissue block. Imaging device (102) may capture an image of the tissue block and store corresponding block data in imaging device (102). Imaging device (102) may obtain the block data based on a user interaction. For instance, a user may provide an input through a user interface (e.g., a graphical user interface (“GUI”)) and request that imaging device (102) image the tissue block. Further, the user may interact with imaging device (102) to cause imaging device (102) to image the tissue block. For instance, the user may toggle a switch of imaging device (102), push a button of imaging device (102), provide a voice command to imaging device (102), or otherwise interact with imaging device (102) to cause imaging device (102) to image the tissue block. In some examples, imaging device (102) may image the tissue block based on detecting, by imaging device (102), that a tissue block has been placed in a viewport of imaging device (102). For instance, imaging device (102) may determine that a tissue block has been placed on a viewport of imaging device (102) and, based on this determination, image the tissue block.

At [B], imaging device (102) obtains slice data. In some examples, imaging device (102) is configured to obtain the slice data and the block data at this stage. In other examples, a first imaging device (102) may obtain the slice and a second imaging device (102) may obtain the block data. In order to obtain the slice data, imaging device (102) may image (e.g., scan, capture, record, etc.) a slice of the tissue block. The slice of the tissue block may be a slice of the histological sample. For instance, the tissue block may be sliced (e.g., sectioned) in order to generate one or more slices of the tissue block. In some examples, a portion of the tissue block may be sliced to generate a slice of the tissue block such that a first portion of the tissue block corresponds to the tissue block imaged to obtain the block data and a second portion of the tissue block corresponds to the slice of the tissue block imaged to obtain the slice data. Imaging device (102) may capture an image of the slice and store corresponding slice data in imaging device (102). In some examples, imaging device (102) is configured to obtain the slice data based on a user interaction. For instance, a user may provide an input through a user interface and request imaging device (102) to image the slice. Further, the user may interact with imaging device (102) to cause imaging device (102) to image the slice. In other examples, imaging device (102) is configured to image the tissue block based on detecting, by imaging device (102), that the tissue block has been sliced or that a slice has been placed in a viewport of imaging device (102).

At [C], imaging device (102) is configured to transmit a signal to image analysis system (108) representing the captured image data (e.g., the block data and the slice data). In particular, imaging device (102) is configured to send the captured image data as an electronic signal to image analysis system (108) via the network (112). The signal may include and/or correspond to a pixel representation of the block data and/or the slice data. It will be understood that the signal may include and/or correspond to more, less, or different image data. For instance, the signal may correspond to multiple slices of a tissue block and may represent a first slice data and a second slice data. Further, the signal may enable image analysis system (108) to reconstruct the block data and/or the slice data. In some examples, imaging device (102) may transmit a first signal corresponding to the block data and a second signal corresponding to the slice data. In other examples, a first imaging device may transmit a signal corresponding to the block data and a second imaging device may transmit a signal corresponding to the slice data.

At [D], image analysis system (108) is configured to perform image analysis on the block data and the slice data provided by imaging device (102). In the present example, image analysis system (108) is configured to perform one or more image processing functions. For instance, image analysis system (108) is configured to perform one or more imaging algorithms. In some examples, image analysis system (108) is configured to use a machine learning model, such as a convolutional neural network, for performing the image processing functions. Based on performing the image processing functions, image analysis system (108) can determine a likelihood that the block data and the slice data correspond to the same tissue block. For instance, in some examples, image processing functions include performance of an edge analysis of the block data and the slice data. Based on such an edge analysis, image analysis system (108) is configured to determine whether the block data and the slice data correspond to the same tissue block. In some examples, image analysis system (108) is configured to determine a confidence threshold based on a response by display device (110) to a particular recommendation. Further, the confidence threshold may be specific to a user, a group of users, a type of tissue block, a location of the tissue block, or any other factor. In such examples, image analysis system (108) is configured to compare the determined confidence threshold with the performed image analysis. Based on this comparison, image analysis system (108) may generate a recommendation indicating a recommended action for display device (110) based on the likelihood that the block data and the slice data correspond to the same tissue block. In other examples, image analysis system (108) is configured to provide a diagnosis regarding whether the image data is indicative of a disease present in the tissue sample, for example, based on the results of a machine learning algorithm.

At [E], image analysis system (108) is configured to communicate a signal to display device (110). In particular, image analysis system (108) is configured to send the signal as an electrical signal to display device (110) via the network (112). The signal may include and/or correspond to a representation of the diagnosis. Based on receiving the signal, display device (110) may determine the diagnosis. In some examples, image analysis system (108) may transmit a series of recommendations corresponding to a group of tissues blocks and/or a group of slices. Image analysis system (108) may include, in the recommendation, a recommended action of a user. For instance, the recommendation may include a recommendation for the user to review the tissue block and the slice. Further, the recommendation may include a recommendation that the user does not need to review the tissue block and the slice.

### II. EXEMPLARY COMPUTING SYSTEM

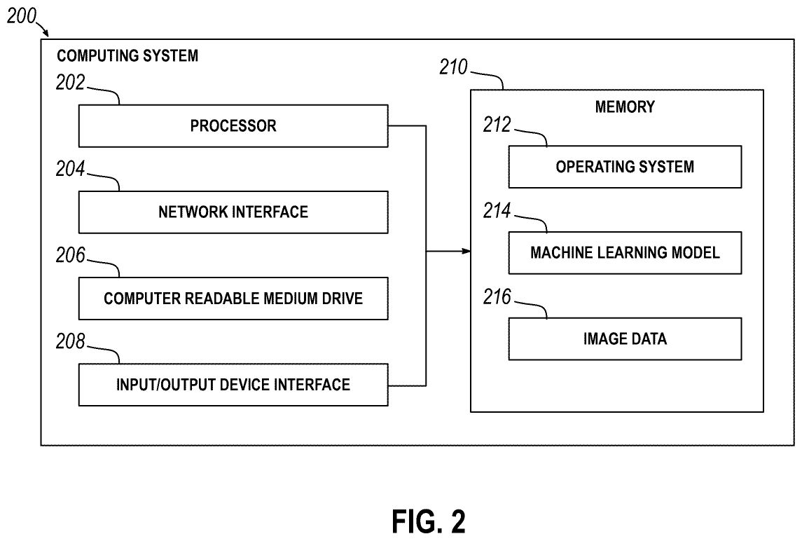

FIG. 2 shows an exemplary computing system (200) that, in various examples, may implement the functionality of one or more of the devices described herein, such as imaging device (102), image analysis system (108), and/or display device (110) of imaging system (100) shown in FIG. 1. As can be seen, computing system (200) includes one or more hardware processors (202), such as physical central processing units (“CPUs”), one or more network interfaces (204), such as a network interface cards (“NICs”), and one or more computer readable medium (206). In some examples, computer readably medium (206) includes, for example, high-density disks (“HDDs”), solid state drives (“SDDs”), flash drives, and/or other persistent non-transitory computer-readable media. Computing system (200) optionally includes an input/output device interface (208), such as an input/output (“IO”) interface in communication with one or more microphones, and one or more non-transitory computer readable memory (or “medium”) (210), such as random-access memory (“RAM”) and/or other volatile non-transitory computer-readable media.

Network interface (204) is configured to provide connectivity to one or more networks or computing systems. Hardware processor (202) is configured receive information instructions from other computing systems or services via network interface (204). Network interface (204) may also store data directly to computer-readable memory (210). Hardware processor (202) may communicate to and from computer-readable memory (210). Hardware processor (202) may execute instructions and process data in computer readable memory (210).

Computer readable memory (210) is configured to store one or more computer program instructions that hardware processor (202) is configured to execute in order to implement one or more examples described herein. Computer readable memory (210) is further configured to store other computer program instructions such an operating system (212). Operating system (212) and/or other associated computer program instructions are configured to provide computer program instructions for use by computer processor (202) in the general administration and operation of computing system (200). Computer readable memory (210) may further include program instructions and other information for implementing aspects of the present disclosure. In one example, computer readable memory (210) includes instructions for training and or executing a machine learning model (214). In other examples, computer readable memory (210) may include image data (216). In another example, computer readable memory (210) includes instructions to classify one or more images based on the trained machine learning model (214).

### II. EXEMPLARY USER INTERFACE FOR ANALYSIS OF DIGITAL WSI'S

As described above, environment or imaging system (100) is configured to perform image analysis on received image data. In some circumstances, it may be desirable to use environment (100) in combination with certain user interface features to facilitate interaction between a user, image data, and any image analysis performed by image analysis system (108). In some circumstances, such image analysis may include output a machine learning algorithm and/or model to facilitate identification of various characteristics of one or more images. Such outputs may be used in combination with user-based analysis modalities such as direct visualization of image data by a user. Thus, it may be desirable to include certain user interface features within environment (100) to facilitate ease of interaction between image analysis performed by image analysis system (108) and user-based analysis modalities.

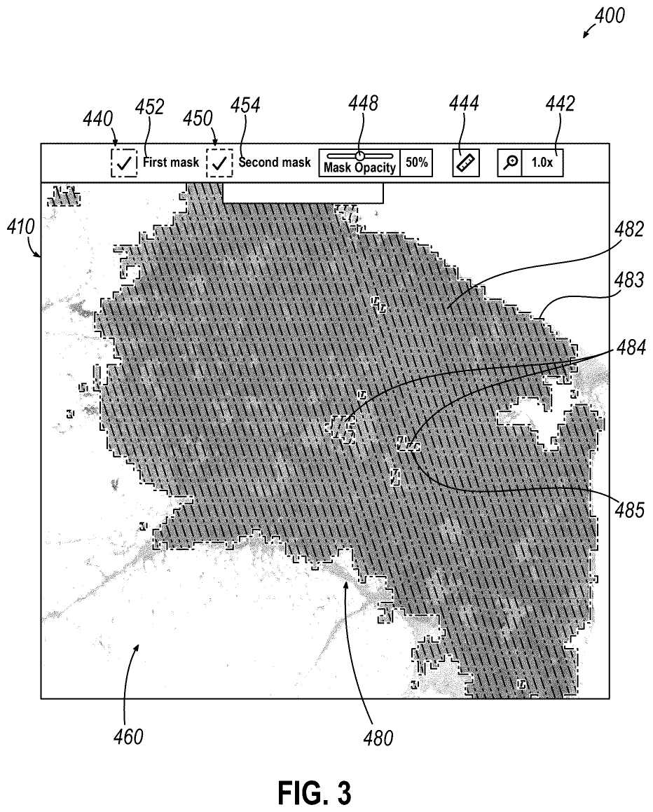

FIGS. 3 through 6 show an exemplary user interface (400) (also referred to as graphical user interface) for use with environment (100) and/or computing system (200) described above. For instance, one or more display devices (110) may be configured to display user interface (400). By way of example only, display devices (110) displaying user interface (400) may be incorporated into a user workstation, such as a network connected personal computer. Thus, in some examples, user interface (400) is configured to be operated by a user remotely relative to other components of environment (100) such as imaging device (102), and/or image analysis system (108).

User interface (400) is generally configured to facilitate viewing and manipulation of one or more digital whole slide images (WSI) acquired using imaging device (102). Thus, user interface (400) includes a display pane (410) for displaying one or more digital WSIs and a tool pane (440) for manipulating one or more digital WSIs. As will be described in greater detail below, display pane (410) is configured to show a variety of layers (460, 480), which may be used to present one or more digital WSIs to a user with varying levels of abstractions.

Tool pane (440) includes a magnification button (442), a measurement button (444), an opacity slider (448), and one or more mask selection checkboxes (450). The features of tool pane (440) are generally driven by one or more computing systems such as computing systems (115, 200) described above. In particular, the features of tool pane (440) described in greater detail below may be manipulated by a user via a display such as display (110) in combination with one or more user input features such as a touch screen, mouse, touch pad, and/or etc. Such computing systems may then receive such user inputs and manipulate the display of one or more digital WSIs presented in display pane (410). Thus, tool pane (440) and display pane (410) may be used in combination with one or more processors, memory, and/or etc. to facilitate manipulation of one or more digital WSIs via tool pane (440) and presented on display pane (410).

Magnification button (442) is generally configured to manipulate one or more digital WSIs through a series of one or more magnification levels. For instance, magnification button (442) may manipulate the particular digital WSI through a plurality of magnification levels such as 1×, 10×, 20×, and 40× upon a user selecting magnification button (442) with each successive selection progressing from one magnification level to another. Optionally, magnification button (442) additionally includes a magnification level indicator configured to communicate the particular level of magnification shown in display pane (410). In the present example, the magnification level indicator is shown as a text box. In other examples, the magnification level indicator may take on a variety of alternative forms such as a graphical level gauge. Although magnification button (442) in the present example is shown as a graphical button, it should be understood that in other examples, magnification button (442) may have a variety of alternative configurations. For instance, in some examples, magnification button (442) is in the form of a graphical slider configured to both permit adjustment of the magnification level and indicate the level graphically simultaneously on one graphical representation.

Measurement button (444) is generally configured to activate a measurement utility feature, which may be used to measure distances between various features in a digital WSI. In the present example, measurement button (444) is positioned between magnification button (442) and opacity slider (448), although a variety of other positions may be used in other examples. Upon selection of measurement button (444), measurement button (444) is configured to initiate a measurement utility sequence using a computing system such as computing systems (115, 200) described above. Upon initiation, a stylized cursor appears (e.g., a cross) to indicate that a user may select one or more features within a digital WSI. Once such one or more features are selected, other features may be selected to measure the distance from one feature to another. Of course, in other examples, the particular implementation of the measurement utility sequence may be varied as will be apparent to those of ordinary skill in the art in view of the teachings herein.

As will be described in greater detail below, opacity slider (448) is generally configured to selectively adjust the appearance one of or more masks or other overlaid features disposed over one or more digital WSIs. Opacity slider (448) includes a graphical slider and an opacity level indicator proximate the graphical slider. The graphical slider is configured to be dragged along a linear continuum to selectively adjust opacity from 1 to 100%. The opacity level indicator is configured to show a numerical indication of the opacity selected by the graphical slider. Although opacity slider (448) is described herein as being used in connection with the image characteristic of opacity, it should be understood that in other examples different image characteristics may be adjusted with a graphical slider substantially similar to opacity slider (448). Additionally, in other examples, opacity slider (448) may be combined with other graphical sliders to adjust different image characteristics simultaneously.

Mask selection checkboxes (450) are generally configured to enable and disable the appearance of certain masks or other overlaid features disposed over one or more digital WSIs, as will be discussed in greater detail below. Each mask selection checkbox (450) incudes a graphical checkbox and a label. Each respective checkbox is configured to selectively enable and disable the appearance of a given mask or other overlaid feature. Each respective checkbox is further configured to indicate an enabled or disabled status by graphically displaying a checkmark, “X” or other indicator. Each respective label includes text to identify which mask selection checkbox (450) corresponds to a given mask or other overlaid feature. Thus, each mask selection checkbox (450) is configured to be graphically selected by a user to toggle one or more masks or other overlaid features between an enabled and disabled state. Although mask selection checkboxes (450) of the present example includes two mask selection checkboxes (450), it should be understood that any suitable number of mask selection checkboxes (450) may be used in other examples.

As described above, display pane (410) is configured to show a variety of layers (460, 480), which may be used to present one or more digital WSIs to a user. Specifically, display pane (410) includes an image layer (460) with one or more mask layers (480) overlayed on top of image layer (460). Image layer (460) is generally configured to present one or more generally non-abstracted digital WSIs to a user within display pane (410). In some examples, the non-abstracted nature of image layer (460) may correspond to a raw digital image output produced by imaging device (102). In other examples, the non-abstracted nature of image layer (460) may include some image processing relative to the raw digital image output produced by imaging device (102). Such image processing may, for example, be performed by image device (102) itself or other components of imaging system (100) such as image analysis system (108). Such image processing may include, for example, edge analysis to eliminate areas without tissue from the image, contrast and sharpness adjustment, color adjustment, focus adjustment, and/or etc.

Mask layers (480) are generally configured to assist users in identifying particular areas of interest within one or more digital WSIs. Thus, mask layers (480) overlay image layer (460) and are adjustable in opacity or transparency to permit observation of one or more masks (482, 484) simultaneously with the content of image layer (460). In other words, mask layers (480) are generally configured to highlight particular regions of interest in one or more digital WSIs. For instance, mask layers (480) include one or more masks (482, 484), which may be generated using a artificial intelligence (AI) or machine learning algorithm implemented by image analysis system (108) and/or one or more computing systems (115, 200) described above. By way of example only, such algorithms may include AI vision algorithms configured to operate as predictive AI to identify structures of tissue that may be indicative of the presence of cancer or other pathologies. Such identification may then be mapped to one or more digital WSIs and presented to a user in the form of one or more masks (482, 484).

Masks (482, 484) in the present example include a first mask (482) corresponding to one structure of interest and a second mask (484) corresponding to another structure of interest. In particular, first mask (482) corresponds to tissue structures identified by the AI or machine learning algorithms described above as having one or more predetermined characteristics (e.g., likely being an invasive tissue structure). Meanwhile, second mask (484) corresponds to tissue structures identified by the AI or machine learning algorithms described above as having one or more alternative predetermined characteristics or combinations of characteristics (e.g., likely being a low-grade ductal carcinoma (DCIS) and/or atypical ductal hyperplasia (ADH)). In some examples, the tissue structures identified by the AI or machine learning algorithms described above may overlap with each other. For instance, some tissue structures identified as having one characteristic associated with first mask (482) may also be identified as having a characteristic associated with second mask (484). Thus, in some examples, masks (482, 484) may be organized in separate mask layers (480) with one mask (482, 484) being prioritized for display over another mask (484, 482) when both masks (482, 484) may otherwise be displayed.

As described above, opacity slider (448) is generally configured to selectively adjust the appearance one of or more masks or other overlaid features disposed over one or more digital WSIs. Thus, in the present example, opacity slider (448) is configured to control the appearance of masks (482, 484) to selectively adjust the appearance thereof. In particular, opacity slider (448) is configured to adjust the opacity of each mask (482, 484) from 0% (not visible or fully transparent) to 100% (fully visible or fully opaque). In the present example, opacity slider (448) is configured to adjust the opacity of both masks (482, 484) simultaneously. In other examples, opacity slider (448) is configured to adjust the opacity of a single mask (482, 484) at a time. In such examples, a toggle or other user interface feature may be included within tool pane (440) to facilitate switching adjustment from one mask (482, 484) to another. In still other examples, multiple sliders substantially similar to opacity slider (448) are used such that each mask (482, 484) has a dedicated adjustment in tool pane (440).

As described above, mask selection checkboxes (450) are generally configured to enable and disable the appearance of certain masks or other overlaid features disposed over one or more digital WSIs. Thus, in the present example, mask selection checkboxes (450) are configured to enable and disable the appearance of masks (482, 484). In particular, first mask box (452) is configured to enable and disable first mask (482), while second mask box (454) is configured to enable and disable second mask (484). Thus, each mask box (452, 454) is operable independently of the other mask box (454, 452) to control whether first mask (482) and second mask (484) are visible.

Each mask (482, 484) in the present example is shown with cross-hatching for illustration purposes in black and white line drawings. Although cross-hatching is used in some examples, the cross-hatching shown in the present example is representative of coloring of each mask (482, 484). In particular, each mask (482, 484) may be a different solid color than the other mask (484, 482). By way of example only, first mask (482) may be the color red or another similar color, while second mask (484) may be the color green or another similar color. In other examples, various alternative colors may be used to facilitate differentiation between masks (482, 484). In addition, in some examples, tool pane (440) may include a color pallet such that the particular color for each mask (482, 484) may be selected by a user.

Each mask (482, 484) includes a respective mask boundary (483, 485) around the perimeter each respective mask (482, 484). Each mask boundary (483, 485) is configured with a distinct appearance relative to an interior of the respective mask (482, 484) to highlight the boundary between different masks (482, 484) and or regions where no mask is present. Such a feature may be particularly desirable at relatively high magnifications where the entirety of a given mask (482, 484) may not be visible. In the present example, each mask boundary (483, 485) is shown using broken lines to represent the difference in appearance between each mask boundary (483, 485) and the respective mask (482, 484). In practice, this difference in appearance is a difference in opacity between each mask boundary (483, 485) and each respective mask (482, 484). In other examples, the difference is a difference in color (e.g., different shades of a similar color or different colors entirely). In still other examples, the difference is a difference in line style such as the use of broken lines as shown. In still other examples, various appearance variations may be combined to distinguish mask boundaries (483, 485) from masks (482, 484).

As best seen in FIGS. 3 through 8, user interface (400) is generally configured to change the appearance of masks (482, 484) and/or mask boundaries (483, 485) when transitioning between different magnification levels. In particular, user interface (400) (as driven by a processor, imaging analysis system (109) and/or computing systems (115, 200)) is configured to automatically adjust the opacity of each mask (482, 484) when transitioning from one magnification level to another. In the present example, the opacity of each mask (482, 484) is adjusted inversely relative to magnification. In other words, as magnification level increases, opacity decreases. Such an inverse relationship is generally desirable to reduce the amount of abstraction of image layer (460) as magnification increases. In particular, at relative low levels of magnification, greater image abstraction may be desirable as fine tissue detail may be less desirable for analysis, while external information provided by masks (482, 484) may be of greater significance. Meanwhile, at relatively high levels of magnification, less image abstraction may be of greater desirability for analysis of fine tissue detail. By applying this inverse relationship automatically, greater efficiency in analysis may be achieved.

FIG. 3 shows user interface (400) when display pane (410) includes a digital WSI at 1× magnification as can be seen by the magnification indicator of magnification button (442). Additionally, both first mask (482) and second mask (484) are visible due to the selection of first mask box (452) and second mask box (454) in mask selection checkboxes (450) of tool pane (440). At the 1× level of magnification, the opacity of both masks (482, 484) is set directly by opacity slider (448). In some examples, the opacity setting at 1× magnification may correspond to a preferred opacity, which may be stored and remain in a memory, such as computer readable medium (206) described above, for subsequent uses. Such a preferred opacity is set by a user in some examples. In other examples, such a preferred opacity is set at a tenant level for a plurality of users. Regardless, in the present example, opacity is initially set at 50%. Thus, masks (482, 484) at 1× magnification are 50% visible or 50% transparent. Although an opacity setting of 50% is used herein, any other suitable opacity setting may be used at 1× magnification in other examples. For instance, in some examples, the opacity setting of 35% may be used.

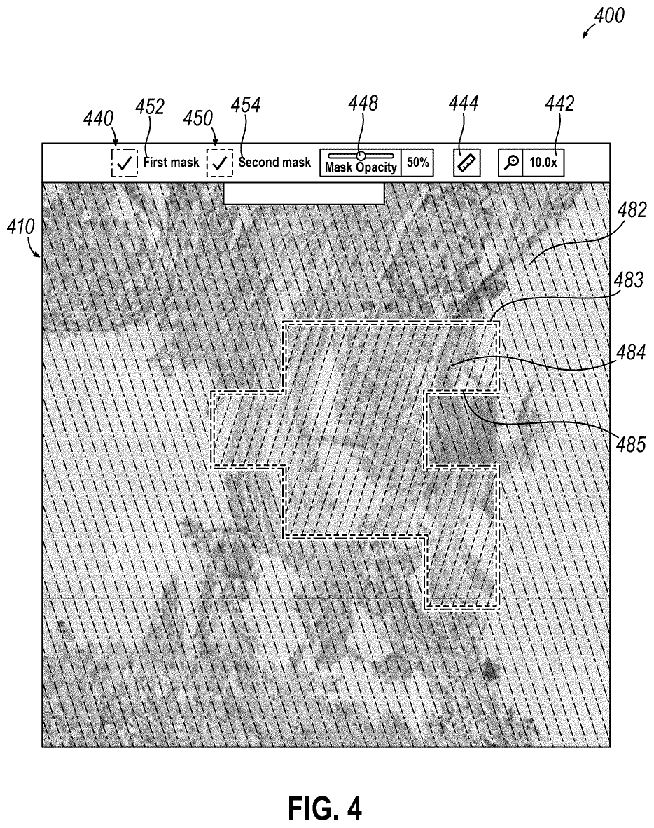

FIG. 4 shows user interface (400) when display pane (410) includes a digital WSI at 10× magnification as can be seen by the magnification indicator of magnification button (442). Additionally, both first mask (482) and second mask (484) are visible due to the selection of first mask box (452) and second mask box (454) in mask selection checkboxes (450) of tool pane (440). At the 10× level of magnification, the opacity of both masks (482, 484) is automatically adjusted relative to opacity shown in FIG. 3 for 1× magnification. In particular, this automatic adjustment is illustrated by the widening cross-hatching shown in FIG. 4 relative to the cross-hatching shown in FIG. 3. Due to the automatic adjustment, opacity slider (448) continues to show the opacity setting set at 1× magnification, or the preferred opacity in some examples.

The adjustment in opacity when transitioning from 1× to 10× magnification may be of a plurality of magnitudes. For instance, in the present example, the opacity is automatically adjusted by 25% relative to the opacity setting at 1× magnification. In other words, the opacity at 10× magnification is reduced to 37.5% opacity versus the 50% opacity at 1× magnification. Thus, masks (482, 484) at 10× magnification are 37.5% visible or 62.5% transparent. In examples where the 1× magnification opacity setting is different than 50% as described above, the same percentage-based reduction may be applied. For instance, if a 35% opacity setting is used at 1× magnification, the opacity setting may be reduced by 25% to 26.25%. In other examples, the reduction in the opacity setting may be an absolute reduction of 25 percentage points. Thus, if a 35% opacity setting is used at 1× magnification, the opacity setting may be reduced to 10% (35% minus 25%). In still other examples, the opacity setting at 10× magnification may have no relationship to the opacity setting at 1× magnification. Thus, in such examples, a fixed opacity setting (e.g., 37.5%) may be used at 10× magnification regardless of the opacity setting set at 1× magnification.

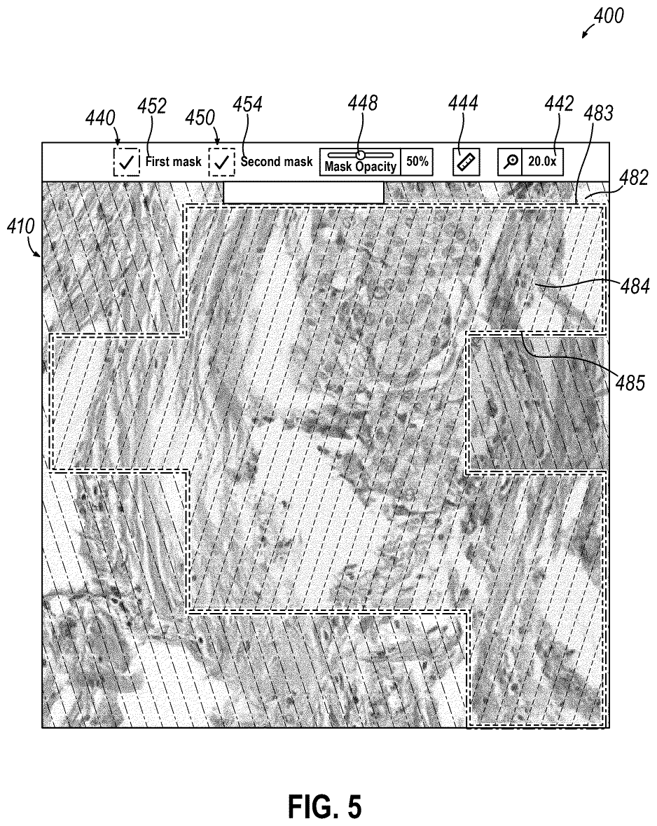

FIG. 5 shows user interface (400) when display pane (410) includes a digital WSI at 20× magnification as can be seen by the magnification indicator of magnification button (442). Additionally, both first mask (482) and second mask (484) are visible due to the selection of first mask box (452) and second mask box (454) in mask selection checkboxes (450) of tool pane (440). At the 20× level of magnification, the opacity of both masks (482, 484) is automatically adjusted relative to opacity shown in FIGS. 3 and 4 for 1× magnification and 10× magnification, respectively. In particular, this automatic adjustment is illustrated by the widening cross-hatching shown in FIG. 5 relative to the cross-hatching shown in FIGS. 3 and 4. Due to the automatic adjustment, opacity slider (448) continues to show the opacity setting set at 1× magnification, or the preferred opacity in some examples.

The adjustment in opacity when transitioning from 1× to 20× magnification or from 10× to 20× magnification may be of a plurality of magnitudes. For instance, in the present example, the opacity is automatically adjusted by 50% relative to the opacity setting at 1× magnification. In other words, the opacity at 20× magnification is reduced to 25% opacity versus the 50% opacity at 1× magnification. Thus, masks (482, 484) at 20× magnification are 25% visible or 75% transparent. In examples where the 1× opacity setting is different than 50% as described above, the same percentage-based reduction may be applied. For instance, if a 35% opacity setting is used at 1× magnification, the opacity setting may be reduced by 50% to 17.5%. In other examples, the reduction in the opacity setting may be an absolute reduction of 30 percentage points relative to the opacity setting at 1× magnification. Thus, if a 35% opacity setting is used at 1× magnification, the opacity setting may be reduced to 5% at 20× magnification. In still other examples, the opacity setting at 10× magnification may have no relationship to the opacity setting at 1× magnification. Thus, in such examples, a 25% opacity setting may be used at 20× magnification regardless of the opacity setting set at 1× magnification.

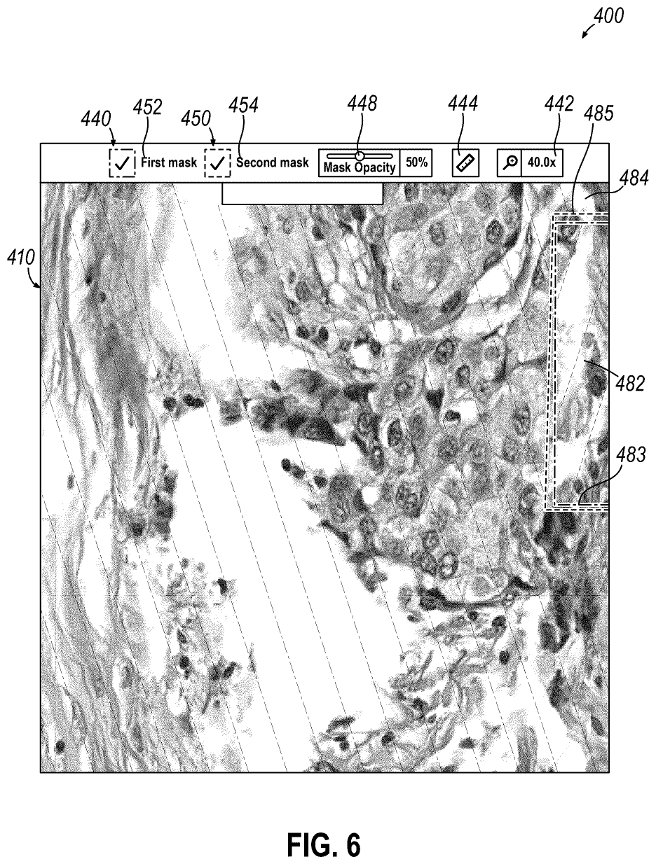

FIG. 6 shows user interface (400) when display pane (410) includes a digital WSI at 40× magnification as can be seen by the magnification indicator of magnification button (442). Additionally, both first mask (482) and second mask (484) are visible due to the selection of first mask box (452) and second mask box (454) in mask selection checkboxes (450) of tool pane (440). At the 40× level of magnification, the opacity of both masks (482, 484) is automatically adjusted relative to opacity shown in FIGS. 3 through 5 for 1× magnification, 10× magnification, and 20× magnification, respectively. In particular, this automatic adjustment is illustrated by the widening cross-hatching shown in FIG. 6 relative to the cross-hatching shown in FIGS. 3 through 5. Due to the automatic adjustment, opacity slider (448) continues to show the opacity setting set at 1× magnification, or the preferred opacity in some examples.

The adjustment in opacity when transitioning from 1× to 40× magnification, from 10× to 40× magnification, or from 20× to 40× magnification may be of a plurality of magnitudes. For instance, in the present example, the opacity is automatically adjusted to a minimum opacity setting. Specifically, 40× magnification in the present example generally corresponds to the highest magnification level. Thus, at 40× magnification, opacity is adjusted to a 0% opacity setting to minimize the abstraction of image layer (460). Although a 0% opacity setting is used in the present example at 40× magnification, it should be understood that in other examples, at least some non-zero opacity setting may be used (e.g., 1 to 10% opacity). In such examples, a non-zero opacity setting may be desirable to provide some visibility of masks (482, 484), while also minimizing abstraction of image layer (460).

As described above, user interface (400) (as driven by a processor, imaging analysis system (109) and/or computing systems (115, 200)) is configured to automatically adjust the opacity of each mask (482, 484) when transitioning from one magnification level to another. Although certain specific opacity adjustment magnitudes are described above with respect to different changes in magnification level, it should be understood that such opacity adjustment magnitudes may be varied in other examples. For instance, as described above, in some examples percentage adjustments may be used for each given magnification level relative to the opacity level set at 1× magnification. In some examples, the percentage adjustment may be common for all magnification levels. Thus, a 25% reduction in opacity may be used for each step increase of magnification, with a 25% reduction at 10× magnification, a 25% reduction (relative to the opacity at 10× magnification) at 20×, and another 25% reduction (relative to the opacity at 20× magnification) at 40×. In other examples, the percentage adjustment may be varied for each magnification level according to a predetermined relationship. For instance, in some examples, the percentage adjustment may be higher at lower magnification level transitions and lower at higher magnification level transitions, thereby forming a tapered opacity adjustment pattern. Of course, other suitable opacity adjustment patterns will be apparent to those of ordinary skill in the art in view of the teachings herein.

Although the appearance of each mask (482, 484) is generally controlled in accordance with the description above as a function of magnification level and an initial or preferred opacity setting, it should be understood that in some examples, one or more portions of each mask (482, 484) is controlled independently of other portions of each mask (482, 484). For instance, as best seen in FIGS. 7 and 8, mask boundaries (483, 485) appear differently at different magnification levels than the internal area of each mask (482, 484). In other words, the appearance of mask boundaries (483, 485) is governed by a different set of rules as executed by a processor than the internal area of masks (482, 484).

In the present example, both mask boundaries (483, 485) appear the same in terms of opacity regardless of magnification level. For instance, FIG. 7 shows the appearance of mask boundaries (483, 485) at a 1× magnification level, while FIG. 8 shows the appearance of mask boundaries (483, 485) at 40× magnification level. As can be seen, the opacity of mask boundaries (483, 485) remains substantially similar between the two magnification levels as illustrated by the substantially similar broken line appearance of each respective mask boundary (483, 485). It should be understood that each mask boundary (483, 485) is shown in broken lines in the present example merely for illustration purposes and in practice, each mask boundary (483, 485) may be in the form of one or more solid lines.

The particular opacity of mask boundaries (483, 485) may be set in a variety of ways. For instance, in the present example, the opacity setting of mask boundaries (483, 485) is a relatively high preset setting. By way of example only, the opacity setting of mask boundaries (483, 485) may be preset to 50 to 90% opacity. Such a preset opacity may further be fixed and unchangeable at the user level. In other examples, the opacity setting of mask boundaries (483, 485) is a function of the initial or preferred opacity setting set at the 1× magnification level. In such examples, the opacity setting of mask boundaries (483, 485) is substantially similar to the initial or preferred opacity setting. In other examples, the opacity setting of mask boundaries (483, 485) is a function of the initial or preferred opacity setting with the opacity setting of mask boundaries (483, 485) being a modified version of the initial or preferred opacity setting.

Although the present example uses a fixed opacity setting for mask boundaries (483, 485) between different magnification levels, it should be understood that in other examples, the opacity setting for mask boundaries (483, 485) may be varied between magnification levels. For instance, in some examples, the opacity for mask boundaries (483, 485) may be varied substantially similarly to the internal area of masks (482, 484) as described above. As similarly described above, the opacity for mask boundaries (483, 485) is set initially at the 1× magnification level. This initial opacity setting is then modified at each magnification level. In other examples, the opacity setting for mask boundaries (483, 485) is adjusted as a function of magnification level like with masks (482, 484), but at a different rate. For instance, the adjustment of the opacity setting for mask boundaries (483, 485) may be less substantial relative to the adjustment for each respective mask (482, 484). As a result, mask boundaries (483, 485) may be more readily visible relative to masks (482, 484). Generally, greater visibility of mask boundaries (483, 485) relative to masks (482, 484) may be desirable to provide information associated with masks (482, 484), while still reducing the image abstraction associated with masks (482, 484).

Although opacity remains substantially similar between the magnification levels for mask boundaries (483, 485) in the present example, it should be understood that other characteristics of mask boundaries (483, 485) may change as a function of magnification level even while opacity remains consistent. For instance, in some examples, the line weight or thickness of each mask boundary (483, 485) is adjustable as a function of magnification level. In some examples, the line weight of each mask boundary (483, 485) increases at lower magnification levels and decreases at higher magnification levels or vice versa. In such examples, line weight adjustment may be desirable to scale the appearance of each mask boundary (483, 485) with the appearance of image layer (460). In addition, or in the alternative, each mask boundary (483, 485) may switch from or between solid and broken lines in some examples. Of course, various additional changes to the characteristics of mask boundaries (483, 485) will be apparent to those of ordinary skill in the art in view of the teachings herein.

### III. EXEMPLARY COMBINATIONS

The following examples relate to various non-exhaustive ways in which the teachings herein may be combined or applied. It should be understood that the following examples are not intended to restrict the coverage of any claims that may be presented at any time in this application or in subsequent filings of this application. No disclaimer is intended. The following examples are being provided for nothing more than merely illustrative purposes. It is contemplated that the various teachings herein may be arranged and applied in numerous other ways. It is also contemplated that some variations may omit certain features referred to in the below examples. Therefore, none of the aspects or features referred to below should be deemed critical unless otherwise explicitly indicated as such at a later date by the inventors or by a successor in interest to the inventors. If any claims are presented in this application or in subsequent filings related to this application that include additional features beyond those referred to below, those additional features shall not be presumed to have been added for any reason relating to patentability.

### Example 1

An apparatus for interacting with one or more digital whole slide images (WSIs) acquired by an imaging device, the apparatus comprising: a display; a memory configured to store computer-executable instructions; and one or more hardware processors in communication with the display and the memory, wherein the one or more hardware processors are configured to drive the display using the computer-executable instructions of the memory such that the one or more hardware processors are configured to: generate a user interface including an image layer and one or more mask layers overlaying the image layer, the one or more mask layers having a predetermined opacity level, and automatically adjust the predetermined opacity level as a function of a magnification level of the image layer.

### Example 2

The apparatus of Example 1, the one or more hardware processors being further configured to adjust the predetermined opacity level in an indirectly proportional relationship to the magnification level of the image layer.

### Example 3

The apparatus of any of Examples 1 or 2, the one or more mask layers including a first mask and a second mask, the one or more hardware processors being further configured to adjust the opacity of the first mask and the second mask simultaneously.

### Example 4

The apparatus of any of Examples 1 through 3, the one or more mask layers including a first mask and a second mask, the first mask having a distinct color relative to the second mask.

### Example 5

The apparatus of Example 4, the distinct color being user selectable.

### Example 6

The apparatus of any of Examples 1 through 5, the one or more hardware processors being further configured to: analyze one or more characteristics of the one or more digital WSIs to generate one or more regions of interest within the one or more digital WSIs, and generate the one or more mask layers based on the one or more regions of interest.

### Example 7

The apparatus of Example 6, the analysis of one or more characteristics of the one or more digital WSIs being performed using a predictive artificial intelligence algorithm.

### Example 8

The apparatus of any of Examples 1 through 7, the one or more hardware processors being further configured to: generate one or more boundary lines associated with each mask layer of the one or more mask layers, and maintain the one or more boundary lines at a consistent opacity as a function of the magnification level of the image layer.

### Example 9

The apparatus of any of Examples 1 through 7, the one or more hardware processors being further configured to: generate one or more boundary lines associated with each mask layer of the one or more mask layers, and maintain a distinct appearance of the one or more boundary lines relative to one or more portions of the one or more mask layers as a function of the magnification level of the image layer.

### Example 10

The apparatus of any of Examples 1 through 7, the one or more hardware processors being further configured to: generate one or more boundary lines associated with each mask layer of the one or more mask layers, and adjust an opacity of the one or more boundary lines as a function of the magnification level of the image layer.

### Example 11

The apparatus of any of claims 1 through 7, the one or more hardware processors being further configured to: generate one or more boundary lines associated with each mask layer of the one or more mask layers, and adjust an opacity of the one or more boundary lines as a function of the magnification level of the image layer, the adjustment of the opacity of the one or more boundary lines being different from the adjustment of the predetermined opacity level of the one or more mask layers.

### Example 12

The apparatus of any of Examples 1 through 11, the predetermined opacity level corresponding to a preferred opacity level.

### Example 13

The apparatus of Example 12, the preferred opacity level being user selectable at a 1× magnification level.

### Example 14

The apparatus of Example 12, the preferred opacity level being set at a tenant level.

### Example 15

The apparatus of any of Examples 1 through 14, further comprising a network interface, the network interface being in communication with a network to receive the one or more digital WSIs from the imaging device.

### Example 16

A non-transitory computer-readable medium having instructions stored thereon, wherein the instructions, when executed by at least one hardware processor of a system, cause the system to: acquire one or more digital whole slide images (WSIs) from an imaging device, the digital WSIs including one or more tissue structures; identify one or more regions of interest within the one or more tissue structures; generate a graphical user interface including an image layer and one or more mask layers, the one or more mask layers including at least one mask overlying the image layer and corresponding to the one or more regions of interest; and automatically adjust an opacity of the mask as a function of a magnification level of the image layer.

### Example 17

The non-transitory computer-readable medium of Example 16, the adjustment of the opacity of the mask is inversely proportional to the magnification level of the image layer.

### Example 18

The non-transitory computer-readable medium of Example 16, the adjustment of the opacity of the mask is relative to a preferred opacity level, the preferred opacity level being user selectable.

### Example 19

The non-transitory computer-readable medium of Example 16, the adjustment of the opacity of the mask including a 25% reduction of opacity relative to a preferred opacity level.

### Example 20

A method for presenting one or more digital whole slide images (WSIs) to a user using a graphical user interface, the method comprising: receiving the one or more digital WSIs from an imaging device; generating a graphical user interface including an image layer depicting the one or more digital WSIs, and a mask layer, the mask layer including a mask overlaying the image layer; setting a preferred opacity level corresponding to the mask; adjusting a magnification level of the one or more digital WSIs depicted in the image layer; and automatically adjusting the preferred opacity level based on the adjustment to the magnification level of the one or more digital WSIs.

### IV. CONCLUSION

It should be appreciated that any patent, publication, or other disclosure material, in whole or in part, that is said to be incorporated by reference herein is incorporated herein only to the extent that the incorporated material does not conflict with existing definitions, statements, or other disclosure material set forth in this disclosure. As such, and to the extent necessary, the disclosure as explicitly set forth herein supersedes any conflicting material incorporated herein by reference. Any material, or portion thereof, that is said to be incorporated by reference herein, but which conflicts with existing definitions, statements, or other disclosure material set forth herein will only be incorporated to the extent that no conflict arises between that incorporated material and the existing disclosure material.

Having shown and described various embodiments of the present invention, further adaptations of the methods and systems described herein may be accomplished by appropriate modifications by one of ordinary skill in the art without departing from the scope of the present invention. Several of such potential modifications have been mentioned, and others will be apparent to those skilled in the art. For instance, the examples, embodiments, geometrics, materials, dimensions, ratios, steps, and the like discussed above are illustrative and are not required. Accordingly, the scope of the present invention should be considered in terms of the following claims and is understood not to be limited to the details of structure and operation shown and described in the specification and drawings.

1. An apparatus for interacting with one or more digital whole slide images (WSIs) acquired by an imaging device, the apparatus comprising:
(a) a display;
(b) a memory configured to store computer-executable instructions; and
(c) one or more hardware processors in communication with the display and the memory, wherein the one or more hardware processors are configured to drive the display using the computer-executable instructions of the memory such that the one or more hardware processors are configured to:
generate a user interface including an image layer and one or more mask layers overlaying the image layer, the one or more mask layers having a predetermined opacity level, and
automatically adjust the predetermined opacity level as a function of a magnification level of the image layer.

2. The apparatus of claim 1, the one or more hardware processors being further configured to adjust the predetermined opacity level in an indirectly proportional relationship to the magnification level of the image layer.

3. The apparatus of claim 1, the one or more mask layers including a first mask and a second mask, the one or more hardware processors being further configured to adjust the opacity of the first mask and the second mask simultaneously.

4. The apparatus of claim 1, the one or more mask layers including a first mask and a second mask, the first mask having a distinct color relative to the second mask.

5. The apparatus of claim 4, the distinct color being user selectable.

6. The apparatus of claim 1, the one or more hardware processors being further configured to:
analyze one or more characteristics of the one or more digital WSIs to generate one or more regions of interest within the one or more digital WSIs, and
generate the one or more mask layers based on the one or more regions of interest.

7. The apparatus of claim 6, the analysis of one or more characteristics of the one or more digital WSIs being performed using a predictive artificial intelligence algorithm.

8. The apparatus of claim 1, the one or more hardware processors being further configured to:
generate one or more boundary lines associated with each mask layer of the one or more mask layers, and
maintain the one or more boundary lines at a consistent opacity as a function of the magnification level of the image layer.

9. The apparatus of claim 1, the one or more hardware processors being further configured to:
generate one or more boundary lines associated with each mask layer of the one or more mask layers, and
maintain a distinct appearance of the one or more boundary lines relative to one or more portions of the one or more mask layers as a function of the magnification level of the image layer.

10. The apparatus of claim 1, the one or more hardware processors being further configured to:
generate one or more boundary lines associated with each mask layer of the one or more mask layers, and
adjust an opacity of the one or more boundary lines as a function of the magnification level of the image layer.

11. The apparatus of claim 1, the one or more hardware processors being further configured to:
generate one or more boundary lines associated with each mask layer of the one or more mask layers, and
adjust an opacity of the one or more boundary lines as a function of the magnification level of the image layer, the adjustment of the opacity of the one or more boundary lines being different from the adjustment of the predetermined opacity level of the one or more mask layers.

12. The apparatus of claim 1, the predetermined opacity level corresponding to a preferred opacity level.

13. The apparatus of claim 12, the preferred opacity level being user selectable at a 1× magnification level.

14. The apparatus of claim 12, the preferred opacity level being set at a tenant level.

15. The apparatus of claim 1, further comprising a network interface, the network interface being in communication with a network to receive the one or more digital WSIs from the imaging device.

16. A non-transitory computer-readable medium having instructions stored thereon, wherein the instructions, when executed by at least one hardware processor of a system, cause the system to:
(a) acquire one or more digital whole slide images (WSIs) from an imaging device, the digital WSIs including one or more tissue structures;
(b) identify one or more regions of interest within the one or more tissue structures;
(c) generate a graphical user interface including an image layer and one or more mask layers, the one or more mask layers including at least one mask overlying the image layer and corresponding to the one or more regions of interest; and
(d) automatically adjust an opacity of the mask as a function of a magnification level of the image layer.

17. The non-transitory computer-readable medium of claim 16, the adjustment of the opacity of the mask is inversely proportional to the magnification level of the image layer.

18. The non-transitory computer-readable medium of claim 16, the adjustment of the opacity of the mask is relative to a preferred opacity level, the preferred opacity level being user selectable.

19. The non-transitory computer-readable medium of claim 16, the adjustment of the opacity of the mask including a 25% reduction of opacity relative to a preferred opacity level.

20. A method for presenting one or more digital whole slide images (WSIs) to a user using a graphical user interface, the method comprising:
(a) receiving the one or more digital WSIs from an imaging device;
(b) generating a graphical user interface including an image layer depicting the one or more digital WSIs, and a mask layer, the mask layer including a mask overlaying the image layer;
(c) setting a preferred opacity level corresponding to the mask;
(d) adjusting a magnification level of the one or more digital WSIs depicted in the image layer; and
(e) automatically adjusting the preferred opacity level based on the adjustment to the magnification level of the one or more digital WSIs.
